(19) United States
(12) Patent Application Publication
(10) Pub. No.: US 2026/0314072 A1
(43) Pub. Date: Oct. 8, 2026

(54) ELECTRO-OPTICAL DEVICE AND ELECTRONIC APPARATUS

(71) Applicant: SEIKO EPSON CORPORATION, Tokyo (JP)

(72) Inventor: Naoto KODAIRA, CHINO-SHI (JP)

(73) Assignee: SEIKO EPSON CORPORATION, Tokyo (JP)

(21) Appl. No.: 19/634,108

(22) Filed: Mar. 31, 2026

(30) Foreign Application Priority Data
Apr. 2, 2025 (JP) 2025-061033

(51) Int. Cl. H10D 86/40; G02F 1/1368; H10D 86/60

(52) U.S. Cl. CPC H10D 86/481; G02F 1/1368; H10D 86/60

(57) ABSTRACT

An electro-optical device includes: a transistor; a pixel electrode disposed at a light incident side of the transistor; a capacitive element including, in a layer between the transistor and the pixel electrode, a capacitance electrode and the other capacitance electrode that is electrically coupled to the transistor and the pixel electrode at a light incident side of the capacitance electrode and is made of a material containing aluminum; and a conductive layer that is formed in a same layer as the capacitance electrode and is electrically coupled to the other capacitance electrode and is electrically coupled to the pixel electrode via a contact hole disposed at a distance from the other capacitance electrode in a plan view.

The present application is based on, and claims priority from JP Application Serial Number 2025-061033, filed Apr. 2, 2025, the disclosure of which is hereby incorporated by reference herein in its entirety.

### BACKGROUND

### 1. Technical Field

The present disclosure relates to an electro-optical device and an electronic apparatus including the electro-optical device.

### 2. Related Art

An electro-optical device described in, for example, JP-A-2019-78825 is known as a related art electro-optical device.

JP-A-2019-78825 describes a liquid crystal panel including capacitive elements each coupled via a pixel contact hole directly below a pixel electrode.

JP-A-2019-78825 is an example of the related art.

In the electro-optical device described in JP-A-2019-78825, a capacitance electrode constituting the capacitive element is formed of titanium nitride. Since the reflectance of titanium nitride is low, most of light incident on the capacitance electrode is not reflected but is absorbed, which causes a rise in temperature of the liquid crystal panel.

### SUMMARY

An electro-optical device according to an aspect of the present application includes: a transistor; a pixel electrode disposed at a light incident side of the transistor; a capacitive element including, in a layer between the transistor and the pixel electrode, a first capacitance electrode and a second capacitance electrode that is electrically coupled to the transistor and the pixel electrode at a light incident side of the first capacitance electrode and is made of a material containing aluminum; and a conductive layer that is formed in a same layer as the first capacitance electrode and is electrically coupled to the second capacitance electrode and is electrically coupled to the pixel electrode via a contact hole disposed at a distance from the second capacitance electrode in a plan view.

An electronic apparatus according to an aspect of the present application includes the electro-optical device described above.

### BRIEF DESCRIPTION OF THE DRAWINGS

FIG. 1 is a plan view of an electro-optical device according to Embodiment 1.

FIG. 2 is a cross-sectional view of the electro-optical device taken along a line II-II in FIG. 1.

FIG. 3 is an equivalent circuit diagram showing an electrical configuration of an element substrate.

FIG. 4 is a diagram illustrating a cross-sectional structure of a display region of the element substrate.

FIG. 5 is a diagram illustrating a planar structure of the display region of the element substrate.

FIG. 6 is a diagram illustrating the planar structure of the display region of the element substrate.

FIG. 7 is a diagram illustrating the planar structure of the display region of the element substrate.

FIG. 8 is a diagram illustrating the planar structure of the display region of the element substrate.

FIG. 9 is a diagram illustrating the planar structure of the display region of the element substrate.

FIG. 10 is a diagram illustrating the planar structure of the display region of the element substrate.

FIG. 11 is a diagram illustrating the planar structure of the display region of the element substrate.

FIG. 12 is a diagram illustrating the planar structure of the display region of the element substrate.

FIG. 13 is a cross-sectional view taken along a line A-A in FIG. 12.

FIG. 14 is a cross-sectional view taken along a line B-B in FIG. 12.

FIG. 15 is a flowchart showing a manufacturing process of a capacitive element and a pixel contact.

FIG. 16 is a cross-sectional view showing an aspect of the manufacturing process.

FIG. 17 is a cross-sectional view showing an aspect of the manufacturing process.

FIG. 18 is a cross-sectional view showing an aspect of the manufacturing process.

FIG. 19 is a cross-sectional view showing an aspect of the manufacturing process.

FIG. 20 is a cross-sectional view showing an aspect of the manufacturing process.

FIG. 21 is a cross-sectional view showing an aspect of the manufacturing process.

FIG. 22 is a plan view showing an aspect of the manufacturing process.

FIG. 23 is a schematic diagram showing an example of an electronic apparatus according to Embodiment 2.

### DESCRIPTION OF EMBODIMENTS

Some embodiments of the present disclosure will hereinafter be described with reference to the drawings.

Note that in the drawings described below, elements may be illustrated at different dimensional scales in accordance with the elements in some cases in order to make the elements eye-friendly.

The description will hereinafter be presented using an X axis, a Y axis, and a Z axis orthogonal to each other as appropriate for the sake of convenience of the explanation. Further, one of directions along the X axis is described as an X1 direction, and a direction opposite to the X1 direction is described as an X2 direction. Similarly, one of directions along the Y axis is described as a Y1 direction, and a direction opposite to the Y1 direction is described as a Y2 direction. One of directions along the Z axis is described as a Z1 direction, and a direction opposite to the Z1 direction is described as a Z2 direction. Hereinafter, viewing in the Z1 direction or the Z2 direction is referred to as "plan view," and viewing in a direction perpendicular to a cross section including the Z axis is referred to as "cross-sectional view."

In the following description, for example, with respect to a substrate, the description "on a substrate" represents any one of when something is disposed in contact with the substrate, when something is disposed above the substrate with another structure intervening therebetween, and when something is disposed so that a part thereof is in contact with the substrate and another part thereof is located above the substrate with another structure intervening therebetween. Further, for example, with respect to the substrate, a description of an "upper surface of the substrate" represents a surface at the Z1 direction side of the substrate, and a description of a "lower surface of the substrate" represents a surface at the Z2 direction side of the substrate.

### 1. Embodiment 1

In the present embodiment, a liquid crystal device 300 will be described as an example of an electro-optical device.

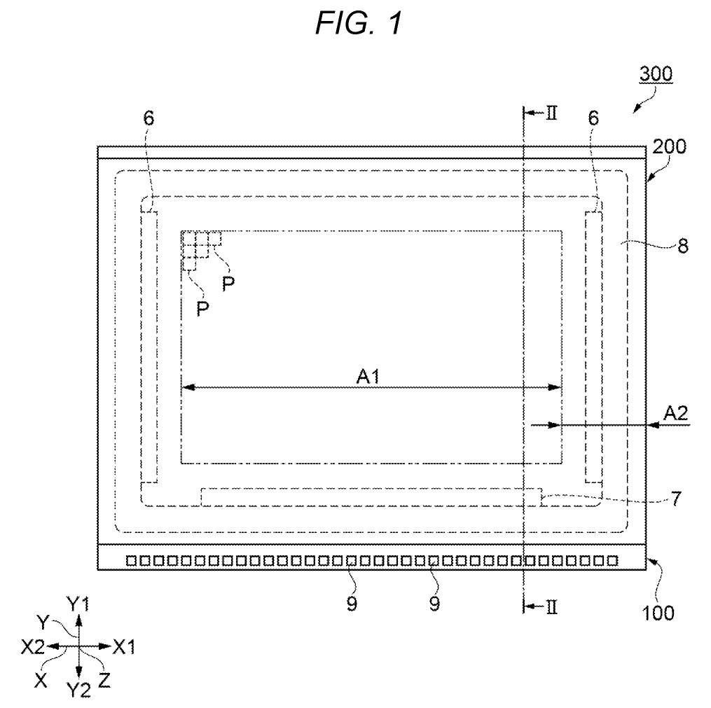

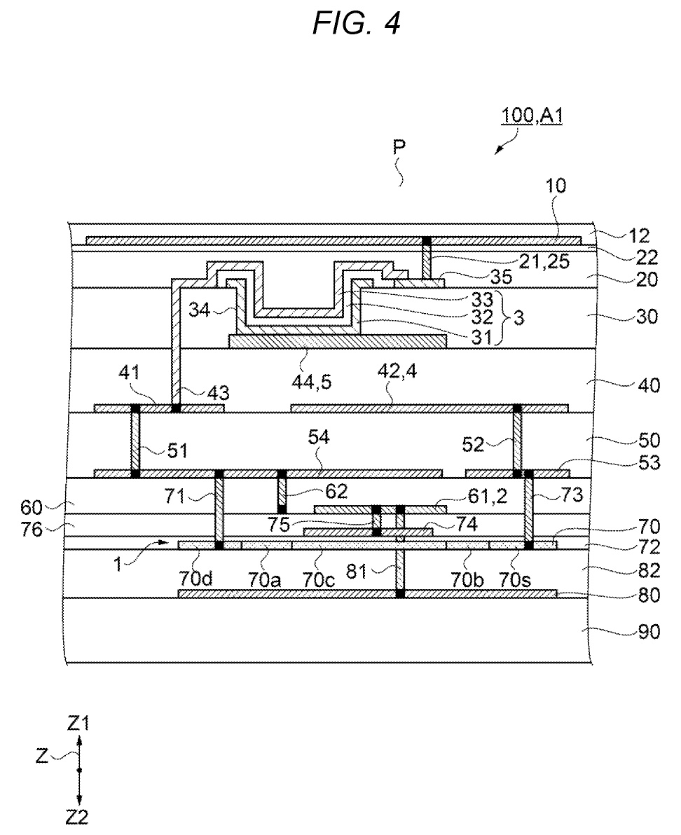

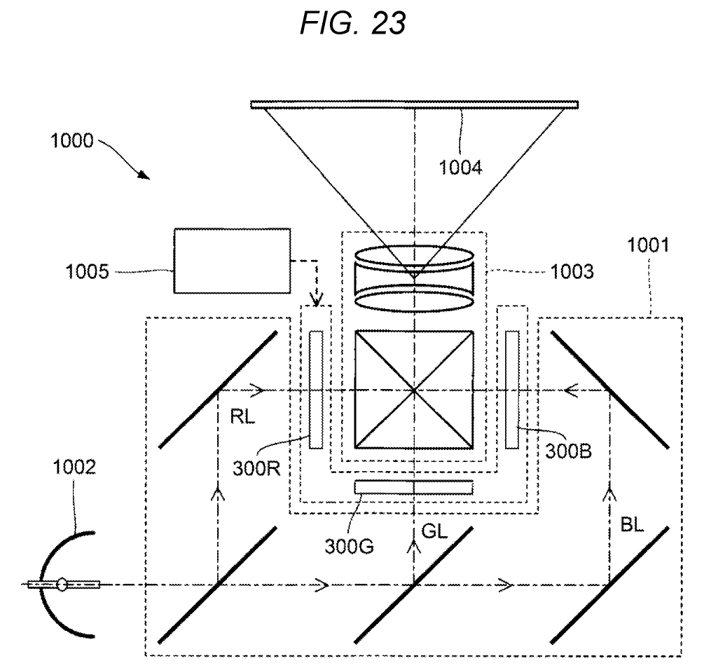

The liquid crystal device 300 (see FIG. 1) is an active drive type transmissive liquid crystal device including a thin film transistor (TFT) as a transistor 1 (see FIG. 4) for each pixel P. The liquid crystal device 300 is used as a light modulation device in, for example, a projection-type display apparatus 1000 (see FIG. 23) described later. In the present embodiment, the projection-type display apparatus 1000 is an example of an electronic apparatus.

### 1.1. Outline of Structure of Liquid Crystal Device 300

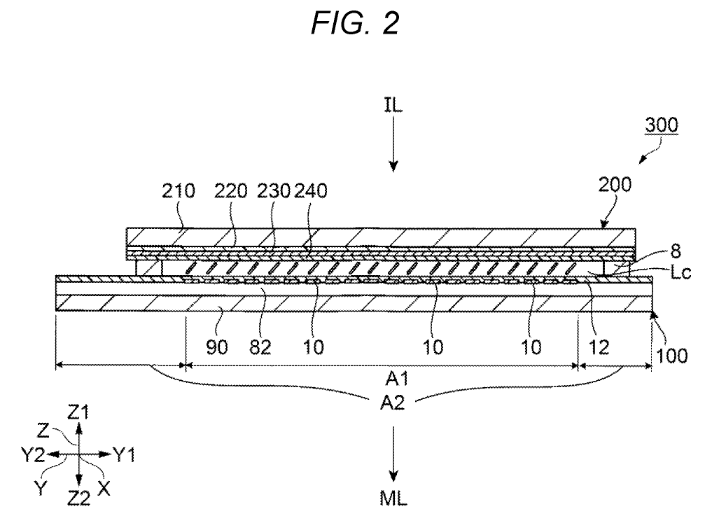

A structure of the liquid crystal device 300 according to the present embodiment will be described with reference to FIGS. 1 and 2. FIG. 1 is a plan view of the liquid crystal device 300. FIG. 2 shows a schematic cross-sectional configuration of the liquid crystal device 300 taken along a line II-II in FIG. 1.

As illustrated in FIGS. 1 and 2, the liquid crystal device 300 includes an element substrate 100 having a light transmissive property, a counter substrate 200 having a light transmissive property, a sealing member 8 disposed in a frame shape, and a liquid crystal layer Lc. Note that the term "light transmissive property" means a transmissive property with respect to visible light, and means that the transmittance for the visible light is preferably no lower than 50 %.

The liquid crystal device 300 has a display region A1, where an image is displayed, and a peripheral region A2 located on the outer periphery of the display region A1 in the plan view.

A plurality of pixels P arranged in a matrix is disposed in the display region A1. Note that the liquid crystal device 300 and the display region A1 shown in FIG. 1 each have a quadrangular shape but may each have other shapes such as a circular shape.

As illustrated in FIG. 2, the element substrate 100 and the counter substrate 200 are disposed via the liquid crystal layer Lc.

In the present embodiment, the counter substrate 200 is disposed at the light incident side of the liquid crystal layer Lc, and the element substrate 100 is disposed at the light exit side of the liquid crystal layer Lc. Incident light IL incident on the counter substrate 200 is modulated by the liquid crystal layer Lc and is output as modulated light ML from the element substrate 100.

The element substrate 100 includes a base 90, a plurality of interlayer insulating layers including an interlayer insulating layer 82, pixel electrodes 10, and an orientation film 12.

A transistor 1 (see FIG. 4), a relay layer, or a conductive layer is disposed between layers of the plurality of interlayer insulating layers. The pixel electrode 10 is disposed at the light incident side of the transistor 1.

The base 90 is a flat plate having a light transmissive property and an insulating property. The base 90 is, for example, a glass substrate or a quartz substrate.

The pixel electrodes 10 each have a light transmissive property. The pixel electrodes 10 are formed of indium tin oxide (ITO). The pixel electrodes 10 may be formed of a transparent conductive material such as indium zinc oxide (IZO) or fluorine-doped tin oxide (FTO). The thickness direction of the pixel electrodes 10 coincides with the Z1 direction or the Z2 direction.

The orientation film 12 has a light transmissive property and an insulating property. The orientation film 12 aligns the liquid crystal molecules of the liquid crystal layer Lc. Examples of the material of the orientation film 12 include silicon oxide (SiO₂) and polyimide.

The counter substrate 200 includes a base 210, an insulating layer 220, a common electrode 230, and an orientation film 240.

The base 210 is a flat plate having a light transmissive property and an insulating property. The base 210 is, for example, a glass substrate or a quartz substrate.

The insulating layer 220 has a light transmissive property and an insulating property. The material of the insulating layer 220 is, for example, an inorganic material such as silicon oxide.

The common electrode 230 is an electrode disposed to face the plurality of pixel electrodes 10, and is also called a counter electrode. The common electrode 230 is formed of a transparent conductive material made of, for example, ITO, IZO, or FTO. The common electrode 230 and each of the pixel electrodes 10 apply an electric field to the liquid crystal layer Lc.

The orientation film 240 has a light transmissive property and an insulating property.

The sealing member 8 is disposed between the element substrate 100 and the counter substrate 200. The sealing member 8 is made of, for example, an adhesive containing various types of curable resin such as epoxy resin. The sealing member 8 may include a gap member formed of an inorganic material such as glass.

The liquid crystal layer Lc is disposed in a region surrounded by the element substrate 100, the counter substrate 200, and the sealing member 8. The liquid crystal layer Lc is an electro-optical layer optical characteristics of which change in accordance with an electric field generated by the pixel electrode 10 and the common electrode 230. The liquid crystal layer Lc contains liquid crystal molecules having positive or negative dielectric anisotropy. The orientation of the liquid crystal molecules changes in accordance with the electric field applied to the liquid crystal layer Lc. The liquid crystal layer Lc modulates the incident light IL in accordance with the electric field applied thereto.

As illustrated in FIG. 1, a plurality of scanning line drive circuits 6, a data line drive circuit 7, and external terminals 9 are disposed in the peripheral region A2 of the element substrate 100.

The external terminals 9 are mounting terminals on which external coupling lines such as flexible printed circuits (FPCs) not shown are mounted. Various signals such as an image signal, a synchronization signal, an inspection signal, a common potential, and a power supply potential are externally supplied to the external terminals 9 via the external coupling lines.

### 1.2. Electrical Configuration of Element Substrate 100

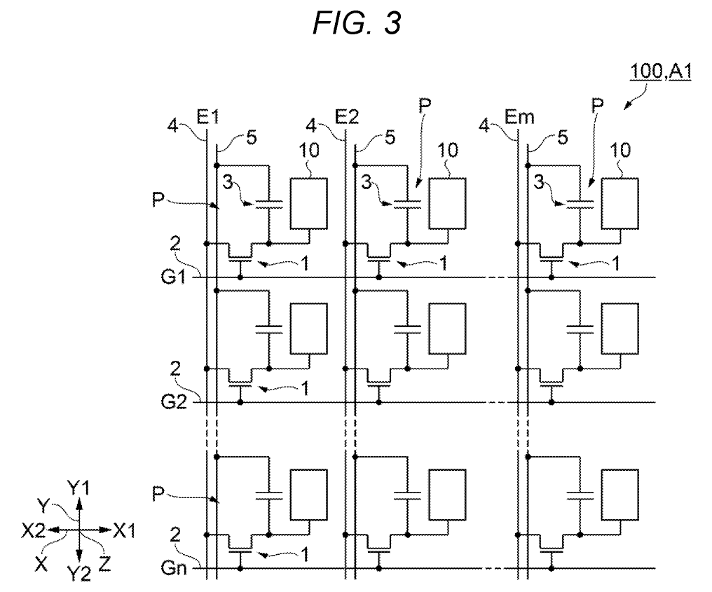

FIG. 3 is an equivalent circuit diagram showing an electrical configuration of the element substrate 100.

As illustrated in FIG. 3, a plurality of transistors 1, n scanning lines 2, m data lines 4, m capacitance lines 5, the pixel electrodes 10, and capacitive elements 3 are disposed in the display region A1 of the element substrate 100. The characters n and m are each an integer no smaller than 2.

The transistor 1 is disposed so as to correspond to each of intersections of the n scanning lines 2 and the m data lines 4. The pixel electrode 10 is electrically coupled to the drain region of the transistor 1.

The n scanning lines 2 each extend in the X1 direction, and are arranged at regular intervals in the Y1 direction. The n scanning lines 2 are each electrically coupled to the gate electrodes of the corresponding transistors 1. The n scanning lines 2 are electrically coupled to the scanning line drive circuits 6 shown in FIG. 1.

The scanning line drive circuit 6 line-sequentially supplies scanning signals G1, G2, …, and Gn to the 1-st to n-th scanning lines 2.

The m data lines 4 each extend in the Y1 direction, and are arranged at regular intervals in the X1 direction. The m data lines 4 are each electrically coupled to the source electrodes of the plurality of corresponding transistors 1. The m data lines 4 are electrically coupled to the data line drive circuit 7 shown in FIG. 1.

The data line drive circuit 7 supplies the image signals E1, E2, …, and Em to the 1-st to m-th data lines 4.

The n scanning lines 2 and the m data lines 4 are electrically insulated from each other and arranged in a grid shape in the plan view. A region surrounded by two adjacent scanning lines 2 and two adjacent data lines 4 corresponds to the pixel P.

The m capacitance lines 5 each extend in the Y1 direction, and are arranged at regular intervals in the X1 direction. The capacitance lines 5 are electrically insulated from the data lines 4 and the scanning lines 2, and are arranged at distances from these lines. A fixed potential such as the common potential or the ground potential is supplied to the capacitance lines 5 via the external terminals 9.

One electrode of the capacitive element 3 is electrically coupled to the capacitance line 5.

The other electrode of the capacitive element 3 is electrically coupled to the pixel electrode 10 and holds the potential of the image signal E1 or the like supplied to the pixel electrode 10.

### 1.3. Cross-Sectional Structure and Planar Structure of Display Region A1 of Element Substrate 100

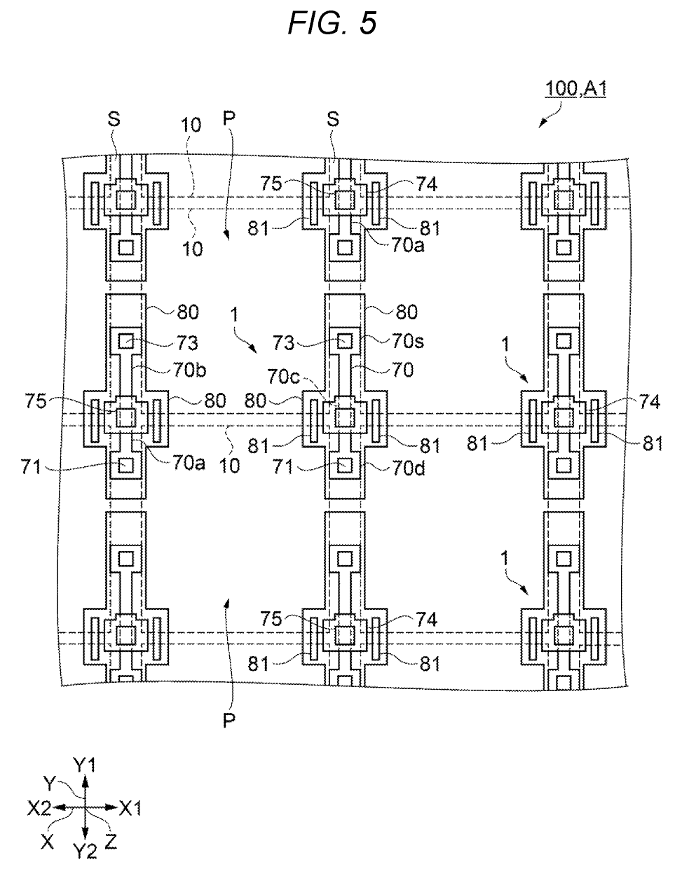

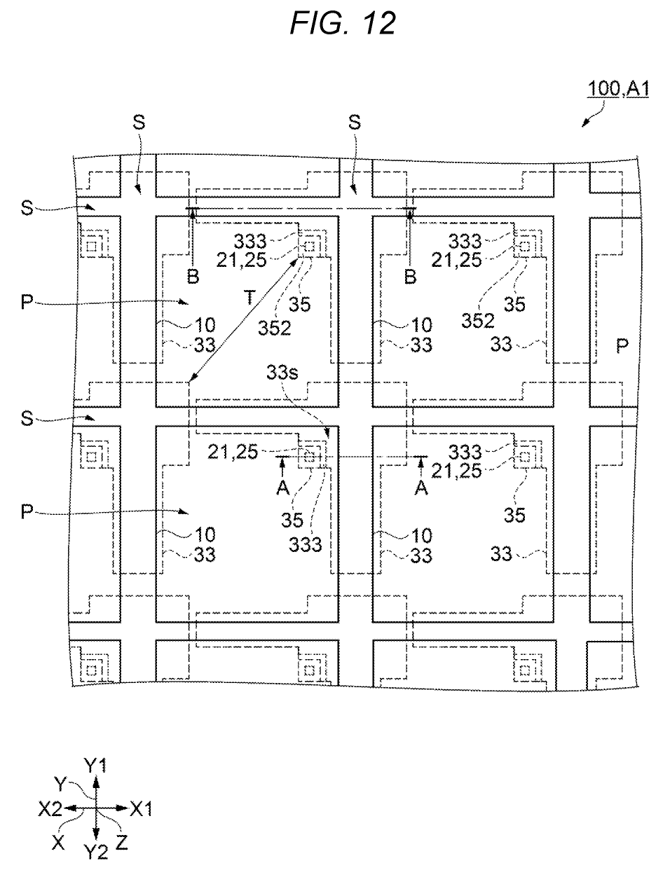

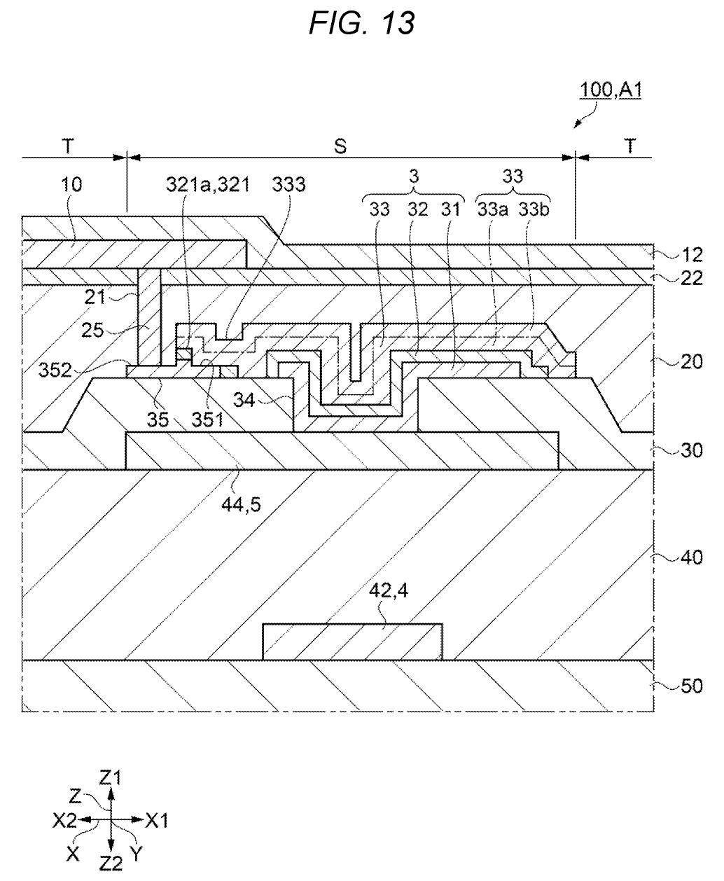

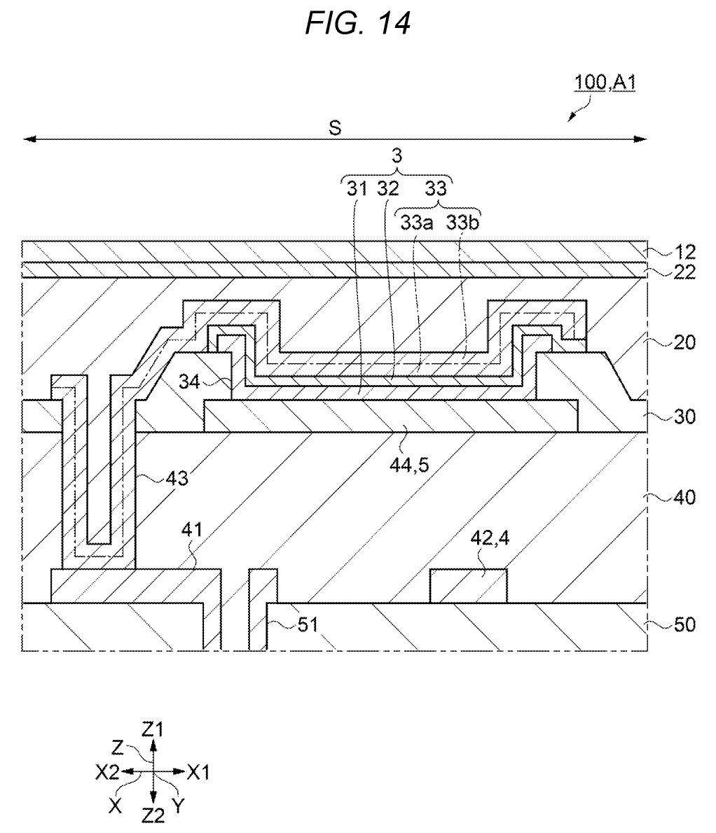

FIG. 4 illustrates a cross-sectional structure of the display region A1 of the element substrate 100, and is a cross-sectional view showing how layers are stacked on each other and how the layers are electrically coupled to each other. FIGS. 5 to 12 are plan views illustrating the planar structures of principal layers. FIG. 13 is a cross-sectional view taken along a line A-A in FIG. 12. FIG. 14 is a cross-sectional view taken along a line B-B in FIG. 12.

As illustrated in FIG. 4, in the display region A1, the element substrate 100 has a cross-sectional structure in which insulating or conductive functional layers or functional films are stacked on the base 90.

FIG. 5 is a plan view illustrating a planar structure of the base 90 to an interlayer insulating layer 76. In FIG. 5, a light blocking layer 80, a semiconductor layer 70, a gate electrode 74, and contact holes 71, 73, 75, and 81 are represented by solid lines. In FIGS. 5 to 9, the position of the pixel electrode 10 is represented by a broken line in order to show a positional relationship of components in the plan view. The pixel electrode 10 has a quadrangular shape.

As illustrated in FIG. 4, the light blocking layer 80 is disposed between the base 90 and the interlayer insulating layer 82.

As illustrated in FIG. 5, the light blocking layer 80 constitutes a part of a light blocking region S of the pixel P, and is disposed so as to overlap the transistor 1 in the plan view. The transistor 1 is disposed to extend in the Y1 direction and the Y2 direction among the four pixel electrodes 10. The light blocking layer 80 has a portion extending in the Y1 direction, a portion extending in the Y2 direction, and a projecting portion that overlaps a corner portion of each of the four pixel electrodes 10.

The light blocking layer 80 is made of a conductive material having a light blocking property. As the conductive material having the light blocking property, it is possible to use metal such as tungsten (W), titanium (Ti), chromium (Cr), iron (Fe), or aluminum (Al), or a metal material such as a metal nitride or a metal silicide. Hereinafter, the conductive material having the light blocking property is substantially the same and functions as the light blocking layer. Note that the term "light blocking property" means a light blocking property with respect to the visible light, and means that the transmittance for the visible light is preferably lower than 50 %, and more preferably no higher than 10 %.

The interlayer insulating layer 82 has a light transmissive property and an insulating property. The interlayer insulating layer 82 is formed of an inorganic material such as silicon oxide (SiO₂). Hereinafter, each of the interlayer insulating layers is made of the same material as that of the interlayer insulating layer 82.

As illustrated in FIG. 4, the transistor 1 is disposed at the interlayer insulating layer 82.

The transistors 1 each include a semiconductor layer 70 having a lightly doped drain (LDD) structure, the gate electrode 74, and a gate insulating layer 72.

The semiconductor layer 70 includes a drain region 70d, an LDD region 70a, a channel region 70c, an LDD region 70b, and a source region 70s.

The channel region 70c is located in a central portion of the semiconductor layer 70. The LDD region 70bis located between the channel region 70c and the source region 70s. The LDD region 70ais located between the channel region 70c and the drain region 70d.

The semiconductor layer 70 is made of, for example, polysilicon, and a region excluding the channel region 70c is doped with an impurity for increasing conductivity. The impurity concentrations in the LDD region 70band the LDD region 70a are lower than those in the source region 70s and the drain region 70d.

The gate electrode 74 is disposed at the semiconductor layer 70 via the gate insulating layer 72.

The gate electrode 74 overlaps the channel region 70c of the semiconductor layer 70.

The gate electrode 74 is formed using, for example, polysilicon doped with an impurity for increasing conductivity. Note that the gate electrode 74 may be formed using a material having conductivity such as metal, metal silicide, or a metal compound.

The gate insulating layer 72 is formed of silicon oxide deposited by, for example, thermal oxidation or chemical vapor deposition (CVD).

The interlayer insulating layer 76 is disposed at the transistor 1.

A conductive layer 61 is disposed at the interlayer insulating layer 76. In the present embodiment, the conductive layer 61 is the scanning line 2.

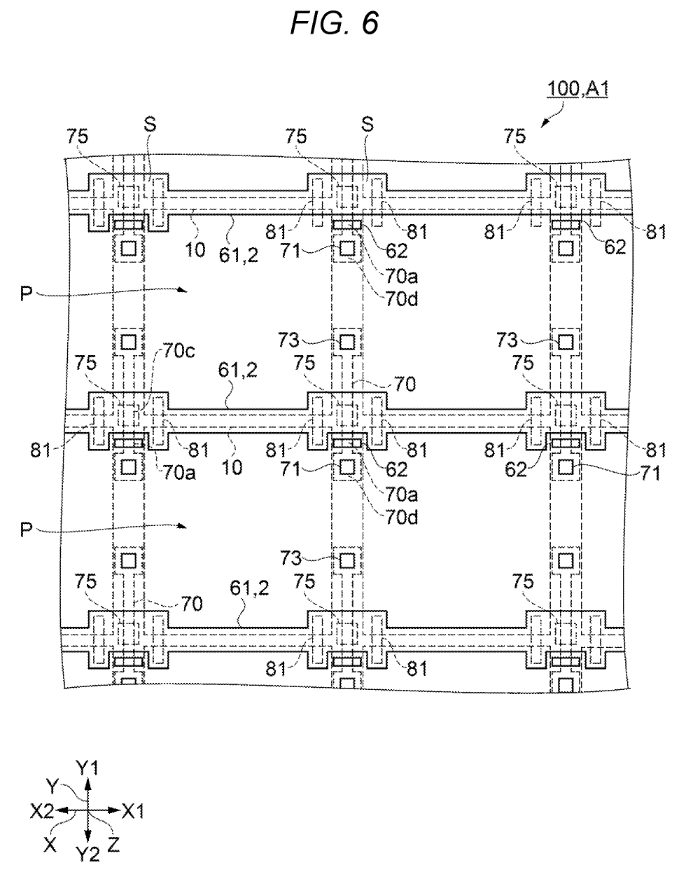

FIG. 6 is a plan view illustrating a planar structure of the conductive layer 61 disposed at the interlayer insulating layer 76, wherein the conductive layer 61, a light blocking member 62, and the contact holes 71, 73 are represented by solid lines, and the contact holes 75, 81 and the semiconductor layer 70 are represented by broken lines.

As shown in FIG. 4, the conductive layer 61 is electrically coupled to the gate electrode 74 via the contact hole 75 provided to the interlayer insulating layer 76. The conductive layer 61 is further electrically coupled to the light blocking layer 80 via the contact hole 81 provided to the interlayer insulating layers 76 and 82. The light blocking layer 80 is supplied with the scanning signal G1 or the like from the conductive layer 61, and thus functions as a back gate.

As illustrated in FIG. 6, the contact hole 81 is disposed along a side surface at the X1 direction side and a side surface at the X2 direction side of the channel region 70c and the LDD region 70a, and the channel region 70c and the LDD region 70a are shielded from light incident from the side surfaces by providing a light blocking member made of a light blocking metal such as tungsten to the contact hole 81.

The conductive layer 61 is formed of a conductive material having a light blocking property and constitutes a part of the light blocking region S of the pixel P. The conductive layer 61 extends in the X1 direction and the X2 direction so as to overlap an area between the pixel electrodes 10 adjacent to each other in the Y1 direction and the Y2 direction. The conductive layer 61 has a projecting portion overlapping a corner portion of the pixel electrode 10.

The light blocking member 62 is disposed so as to overlap the LDD region 70a in the plan view. As illustrated in FIG. 4, the light blocking member 62 is electrically coupled to a relay layer 54, and the potential of the drain region 70d is applied to the light blocking member 62 via the contact hole 71 and the relay layer 54.

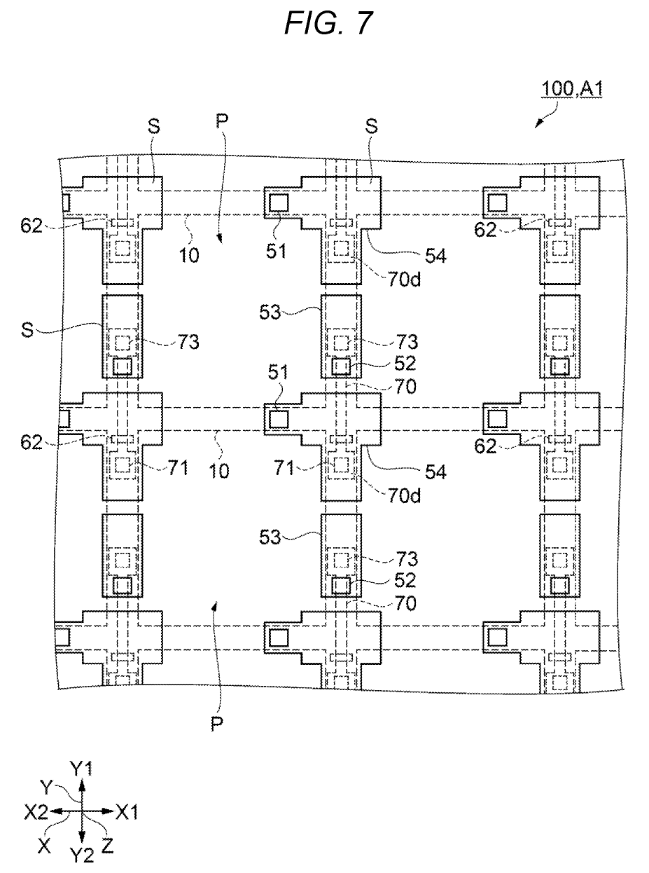

FIG. 7 is a plan view illustrating a planar structure of a relay layer 53 and the relay layer 54, wherein the relay layers 53, 54 and contact holes 51, 52 are represented by solid lines, and the contact holes 71, 73, the light blocking member 62, and the semiconductor layer 70 are represented by broken lines.

The relay layer 53 and the relay layer 54 are formed of a conductive material having a light blocking property, and constitute a part of the light blocking region S of the pixel P. The relay layer 53 and the relay layer 54 are disposed so as to overlap an area between the pixel electrodes 10 adjacent to each other in the X1 direction and the X2 direction.

The relay layer 54 is disposed at a position where the relay layer 54 overlaps corner portions of the four pixel electrodes 10, and has a projecting portion overlapping the corner portion of each of the pixel electrodes 10.

As illustrated in FIG. 4, the relay layer 54 is electrically coupled to the drain region 70d of the semiconductor layer 70 via the contact hole 71 provided to the interlayer insulating layers 60 and 76.

The relay layer 53 is electrically coupled to the source region 70s of the semiconductor layer 70 via the contact hole 73 provided to the interlayer insulating layers 60 and 76.

The interlayer insulating layer 50 is disposed at the relay layer 53 and the relay layer 54, and a relay layer 41 and a conductive layer 42 are disposed at the interlayer insulating layer 50.

In the present embodiment, the conductive layer 42 is the data line 4. The relay layer 41 and the conductive layer 42 are provided in the same layer and are each formed of a conductive material having a light blocking property.

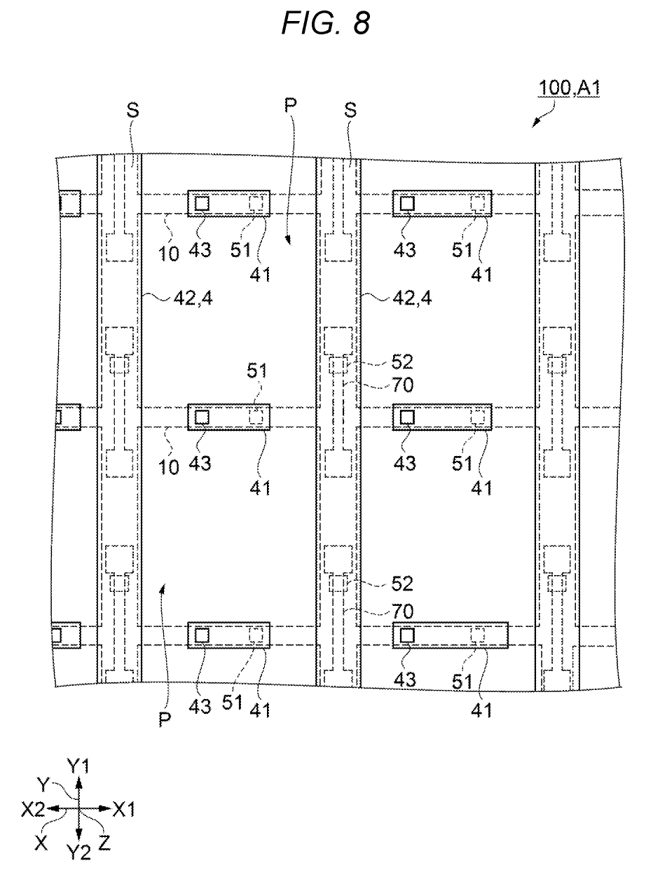

FIG. 8 is a plan view illustrating a planar structure of the relay layer 41 and the conductive layer 42, wherein the relay layer 41, the conductive layer 42, and a contact hole 43 are represented by solid lines, and the contact holes 51, 52 and the semiconductor layer 70 are represented by broken lines.

The relay layer 41 and the conductive layer 42 are formed of a conductive material having a light blocking property and constitute a part of the light blocking region S of the pixel P.

The relay layer 41 is disposed so as to overlap an area between the pixel electrodes 10 adjacent to each other in the Y1 direction and the Y2 direction.

The conductive layer 42 extends in the Y1 direction and the Y2 direction so as to overlap an area between the pixel electrodes 10 adjacent to each other in the X1 direction and the X2 direction, and is disposed so as to overlap the semiconductor layer 70.

As illustrated in FIG. 4, the relay layer 41 is electrically coupled to the relay layer 54 via the contact hole 51. The conductive layer 42 is electrically coupled to the relay layer 53 via the contact hole 52.

An interlayer insulating layer 40 is disposed at the relay layer 41, the conductive layer 42, and the interlayer insulating layer 50. A conductive layer 44 and an interlayer insulating layer 30 are disposed at the interlayer insulating layer 40. The capacitive element 3 and a conductive layer 35 are disposed at the conductive layer 44 and the interlayer insulating layer 30. In the present embodiment, the conductive layer 44 is the capacitance line 5.

A part of the capacitive element 3 is disposed along a trench 34 provided to the interlayer insulating layer 30.

The capacitive element 3 includes a capacitance electrode 31, a capacitance insulating layer 32, and a capacitance electrode 33.

The capacitance electrode 31 is electrically coupled to the conductive layer 44 exposed in the trench 34, and is supplied with a common potential via the conductive layer 44. The capacitance electrode 31 is made of a conductive material having a light blocking property. In the present embodiment, the capacitance electrode 31 is an example of a first capacitance electrode.

The capacitance electrode 33 is electrically coupled to the relay layer 41 via the contact hole 43. The capacitance electrode 33 is made of a conductive material having a light blocking property. The capacitance electrode 33 is a light blocking layer located closest to the pixel electrode 10, and has a function as a light reflection layer. In the present embodiment, the capacitance electrode 33 is an example of a second capacitance electrode.

The conductive layer 35 and the capacitance electrode 31 are disposed at the interlayer insulating layer 30. In the present embodiment, the conductive layer 35 and the capacitance electrode 31 are conductive layers in the same layer. The conductive layer 35 and the capacitance electrode 31 are formed by patterning the conductive layers formed of the same material and in the same process.

The conductive layer 35 is electrically coupled to the capacitance electrode 33 and is electrically coupled to the pixel electrode 10 via a contact hole 21 disposed at a distance from the capacitance electrode 33. As illustrated in FIG. 12, the contact hole 21 is disposed at a distance from the capacitance electrode 33 in the plan view.

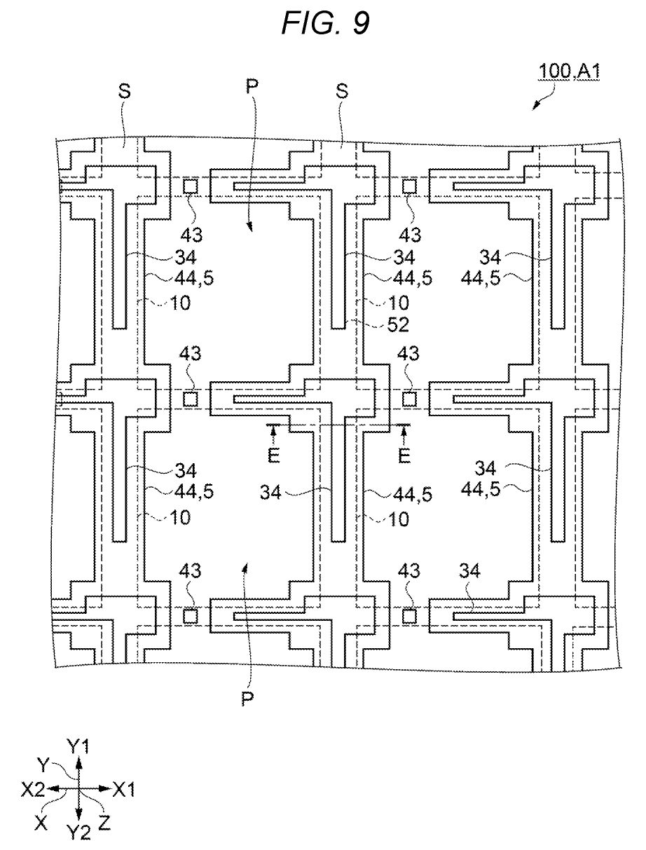

FIG. 9 is a plan view illustrating a planar structure of the conductive layer 44, the trench 34, and the contact hole 43, wherein the conductive layer 44, the trench 34, and the contact hole 43 are represented by solid lines.

The conductive layer 44 is formed of a conductive material having a light blocking property and constitutes a part of the light blocking region S of the pixel P.

The trench 34 is provided to the interlayer insulating layer 30 and exposes the conductive layer 44 at the bottom of the trench 34. The trench 34 is formed in an inverted L shape in the plan view.

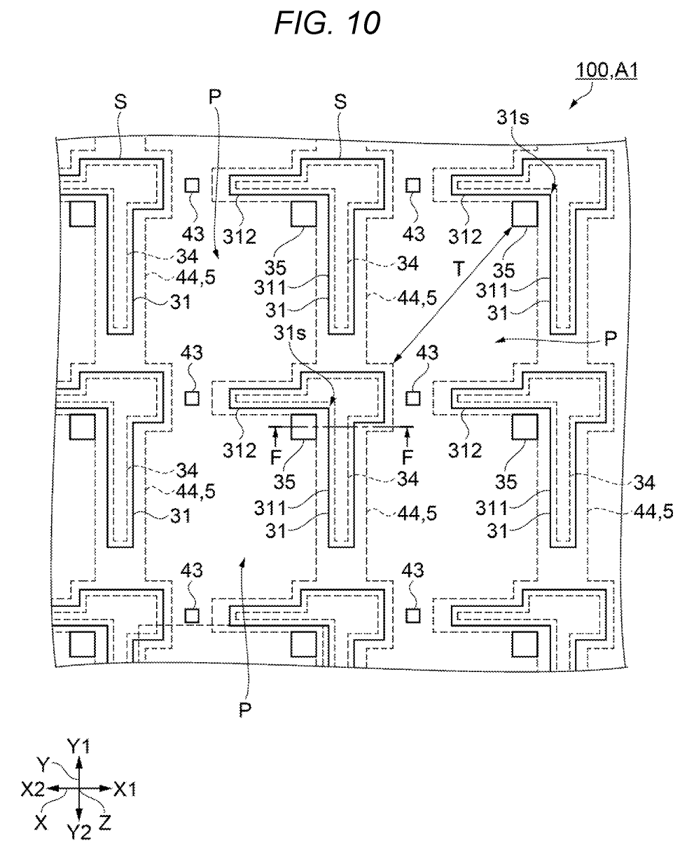

FIG. 10 is a plan view illustrating a planar structure of the capacitance electrode 31, the conductive layer 35, the conductive layer 44, the contact hole 43, and the trench 34, wherein the capacitance electrode 31, the conductive layer 35, and the contact hole 43 are represented by solid lines, and the conductive layer 44 and the trench 34 are represented by broken lines.

The capacitance electrode 31 is formed of a conductive material having a light blocking property and constitutes a part of the light blocking region S of the pixel P. The capacitance electrode 31 has an inverted L shape in the plan view, and includes an extending portion 311 extending in the Y2 direction and an extending portion 312 extending in the X2 direction.

The conductive layer 35 is disposed at an opening T side of the pixel P in a corner portion 31s defined by the extending portion 311 and the extending portion 312. Here, the opening T is a region that does not overlap the light blocking region S of the pixel P in the plan view. The opening T can be reworded as a light transmissive region.

The capacitance electrode 31, the capacitance electrode 33, and the conductive layer 44 are each formed of a conductive material having a light blocking property, and constitute a part of the light blocking region S of the pixel P.

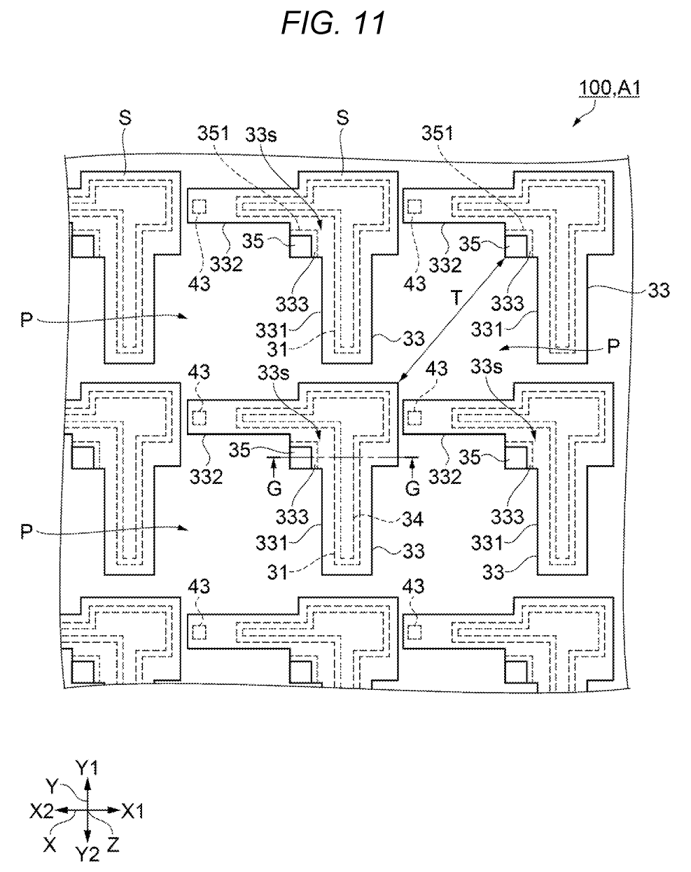

FIG. 11 is a plan view illustrating a planar structure of the capacitance electrode 33, the conductive layer 35, the capacitance electrode 31, the trench 34, and the contact hole 43, wherein the capacitance electrode 33 and the conductive layer 35 are represented by solid lines, and the capacitance electrode 31, the trench 34, and the contact hole 43 are represented by broken lines.

The capacitance electrode 33 is formed of a conductive material having a light blocking property and constitutes a part of the light blocking region S of the pixel P. The capacitance electrode 33 has an inverted L shape in the plan view, and includes an extending portion 331 extending in the Y2 direction and an extending portion 332 extending in the X2 direction.

Further, the capacitance electrode 33 includes a protruding portion 333 protruding toward the opening T of the pixel P in a corner portion 33s defined by the extending portion 331 and the extending portion 332. In the present embodiment, the Y2 direction is an example of a first direction, the extending portion 331 is an example of a first extending portion, the X2 direction is an example of a second direction, and the extending portion 332 is an example of a second extending portion.

The capacitance electrode 33 overlaps the contact hole 43 in the plan view and is electrically coupled to the relay layer 41 via the contact hole 43.

At least a part of the protruding portion 333 of the capacitance electrode 33 overlaps an end portion of the conductive layer 35 in the plan view, and the capacitance electrode 33 is electrically coupled to the conductive layer 35 in the end portion of the conductive layer 35 where the capacitance electrode 33 and the conductive layer 35 overlap each other. A region 351 described later is disposed in the end portion of the conductive layer 35. In the present embodiment, the region 351 is an example of an end portion and an example of a first region.

FIG. 12 is a plan view illustrating a planar structure of the pixel electrode 10, the capacitance electrode 33, the conductive layer 35, the contact hole 21, and a contact plug 25, wherein the pixel electrode 10 is represented by a solid line, and the capacitance electrode 33, the conductive layer 35, the contact hole 21, and the contact plug 25 are represented by a broken line.

As illustrated in FIG. 4, by disposing the capacitance line 5 between the data line 4, and the capacitance electrode 33 and the conductive layer 35, an area between the data line 4, and the capacitance electrode 33 and the conductive layer 35 is shielded by the capacitance line 5, and thus, electrical coupling between the data line 4, and the capacitance electrode 33 and the conductive layer 35 is suppressed. Therefore, it is possible to prevent the image signal E1 and so on of other pixels P supplied to the data lines 4 from being applied as noise to the capacitance electrode 33 and the conductive layer 35.

An interlayer insulating layer 20 and a protective layer 22 are disposed at the capacitance electrode 33 and the conductive layer 35. The protective layer 22 is made of an inorganic material having a light transmissive property and a hygroscopic property such as borosilicate glass (BSG). The protective layer 22 may be omitted. The pixel electrode 10 is disposed at the protective layer 22.

The pixel electrode 10 is electrically coupled to the conductive layer 35 via the contact hole 21 provided to the interlayer insulating layer 20 and the protective layer 22. The contact plug 25 is disposed in the contact hole 21. The contact hole 21 and the contact plug 25 constitute a pixel contact. In the present embodiment, the pixel contact is a component that electrically couples the pixel electrode 10 and the conductive layer 35 immediately below the pixel electrode 10.

### 1.4. Capacitive Element 3 and Pixel Contact

FIG. 13 is a cross-sectional view taken along a line A-A in FIG. 12, and illustrates a cross-sectional configuration of the capacitive element 3 and the pixel contact. FIG. 14 is a cross-sectional view taken along a line B-B in FIG. 12 and illustrates a cross-sectional configuration of the capacitive element 3.

As illustrated in FIG. 13, the pixel contact electrically couples the pixel electrode 10 and the conductive layer 35. In the present embodiment, the pixel contact includes the contact hole 21 and the contact plug 25. The pixel contact may be formed of the contact hole 21 and the pixel electrode 10 deposited in the contact hole 21.

The conductive layer 35 is electrically coupled to the capacitance electrode 33. In the present embodiment, the capacitance electrode 33 is electrically coupled to the pixel electrode 10 via the conductive layer 35.

The conductive layer 35 has, on an upper surface thereof, the region 351 and a region 352 exposed from an insulating layer 321. The region 351 is disposed at the opposite side of the opening T of the pixel P of the insulating layer 321 in the plan view, and the region 352 is disposed at the opening T side of the pixel P of the insulating layer 321 in the plan view.

The capacitance electrode 33 overlaps the region 351. The conductive layer 35 is electrically coupled to the capacitance electrode 33 in the region 351.

The contact hole 21 overlaps the region 352. The contact hole 21 is disposed at a distance from the capacitance electrode 33 in the region 352. In the present embodiment, the region 352 is an example of a second region.

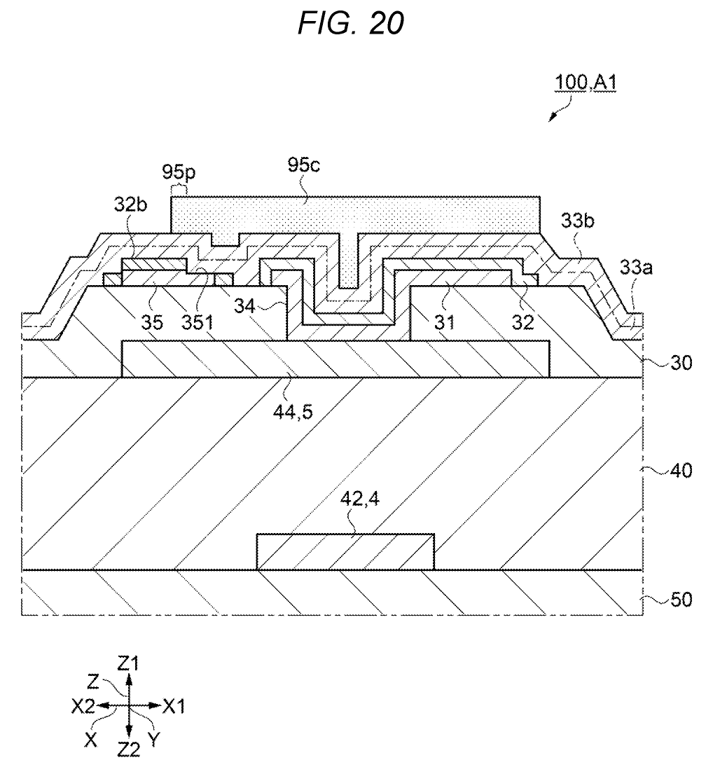

The insulating layer 321 covers the conductive layer 35 between the region 351 and the region 352. The insulating layer 321 is a portion where a part of an insulating layer 32b (see FIG. 20) remains when the region 352 is formed. By leaving the insulating layer 321 on the conductive layer 35 between the region 351 and the region 352, the region 352 can be processed with high quality. That is, it is possible to suppress the conductive layer 35 from being excessively etched by the etching when the region 352 is formed, and to suppress the occurrence of defects such as penetration or disappearance.

The contact hole 21 penetrates the interlayer insulating layer 20 and the protective layer 22 to reach the conductive layer 35. The contact plug 25 is disposed in the contact hole 21. The contact plug 25 contains tungsten. Tungsten is a material that has excellent heat resistance and is easily embedded in a contact hole having a high aspect ratio. Therefore, tungsten can completely fill the elongated contact hole 21. Therefore, the reliability of the contact plug 25 as a coupling member can be improved.

Although not illustrated, a barrier member may be disposed between the contact plug 25 and the contact hole 21. The barrier member is formed of tungsten nitride (WN) or titanium nitride. Tungsten nitride or titanium nitride has excellent adhesion to the interlayer insulating layer 20. Therefore, the barrier member can suppress separation of the contact plug 25 to thereby improve the reliability of the contact plug 25.

The capacitance electrode 33 includes a conductive film 33a and a conductive film 33b disposed at the conductive film 33a.

The conductive film 33a includes titanium nitride (TiN). The conductive film 33bcontains aluminum. Aluminum is higher in optical reflectance than titanium nitride. Therefore, the conductive film 33bfunctions as a light reflection layer. Specifically, the conductive film 33breflects about 90 % of the light applied to the capacitance electrode 33. In other words, the conductive film 33bcan reduce the light absorbed by the capacitance electrode 33 out of the light applied thereto to about 10 %.

Therefore, the liquid crystal device 300 of the present embodiment can suppress a rise in temperature of the liquid crystal device 300. In the present embodiment, the conductive film 33ais an example of a first film, and the conductive film 33b is an example of a second film.

As illustrated in FIG. 14, the capacitance electrode 33 is deposited in the contact hole 43 and is electrically coupled to the relay layer 41 at the bottom of the contact hole 43.

### 1.5. Method Of Manufacturing Capacitive Element 3 and Pixel Contact

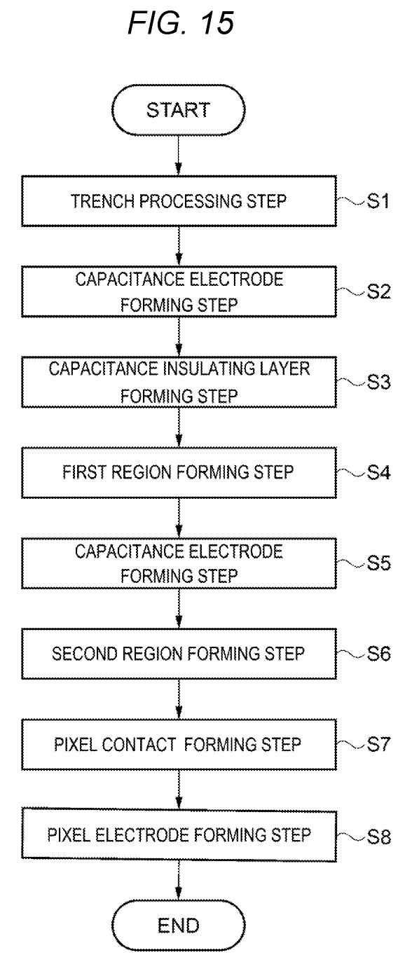

Then, a method of manufacturing the capacitive element 3 and the pixel contact will be described with reference to FIGS. 15 to 22.

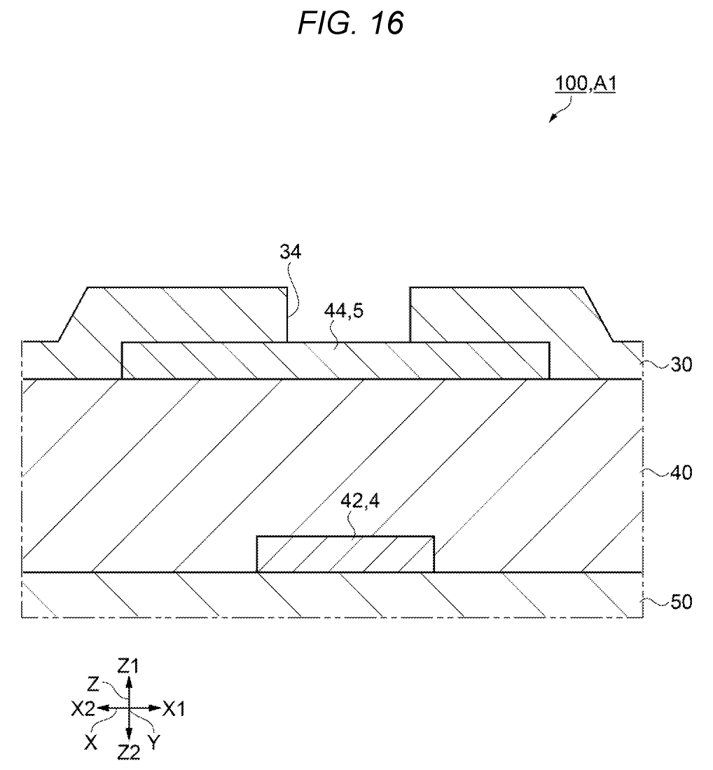

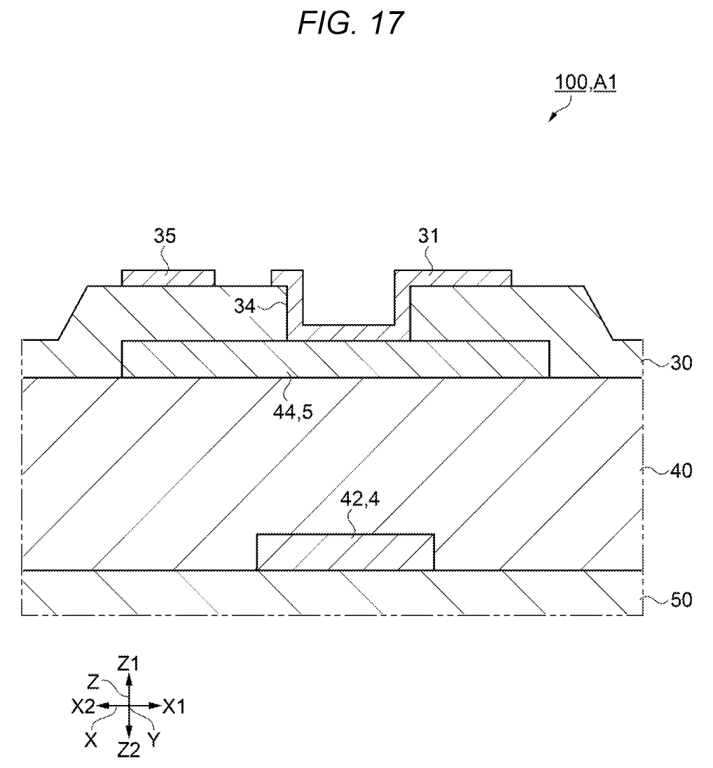

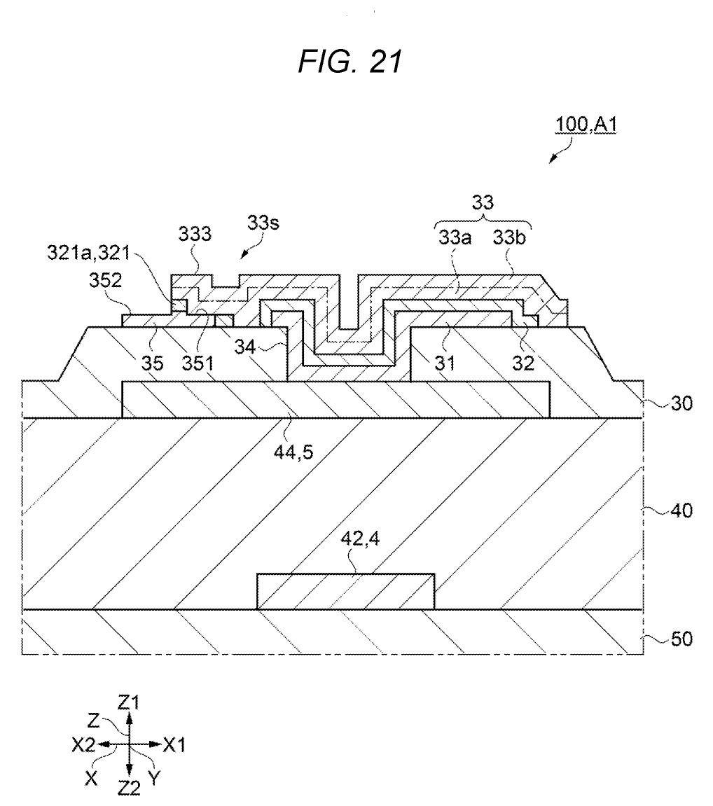

FIG. 15 is a flowchart illustrating the method of manufacturing the capacitive element 3 and the pixel contact. FIGS. 16 to 22 are cross-sectional views or plan views illustrating an aspect of a manufacturing process of the capacitive element 3 and the pixel contact. FIG. 16 corresponds to a cross section taken along a line E-E in FIG. 9. FIGS. 17 to 19 correspond to a cross section taken along a line F-F in FIG. 10. FIGS. 20 and 21 correspond to a cross section taken along a line G-G in FIG. 11.

As illustrated in FIG. 15, the method of manufacturing the capacitive element 3 and the pixel contact includes a trench processing step S1, a capacitance electrode forming step S2, a capacitance insulating layer forming step S3, a first region forming step S4, a capacitance electrode forming step S5, a second region forming step S6, a pixel contact forming step S7, and a pixel electrode forming step S8.

In the trench processing step S1, as shown in FIG. 16, the trench 34 exposing the conductive layer 44 at a bottom of a groove is provided to the interlayer insulating layer 30 at the conductive layer 44.

In the capacitance electrode forming step S2, as illustrated in FIG. 17, the capacitance electrode 31 and the conductive layer 35 are formed at the interlayer insulating layer 30. The capacitance electrode 31 is a first capacitance electrode of the capacitive element 3, and the conductive layer 35 relays the pixel electrode 10 and the capacitance electrode 33 which is a second capacitance electrode of the capacitive element 3.

A part of the capacitance electrode 31 is formed in the trench 34. The capacitance electrode 31 and the conductive layer 35 are formed in the same process and from the same material.

The conductive layer 35 is preferably deposited to have a layer thickness no smaller than 1500 Å. Since the conductive layer 35 is half-etched in the first region forming step S4 and the second region forming step S6, the process margin can be increased by forming the conductive layer 35 as a thick film. Therefore, it becomes easy to form the regions 351, 352 in the conductive layer 35, and the yield can be improved.

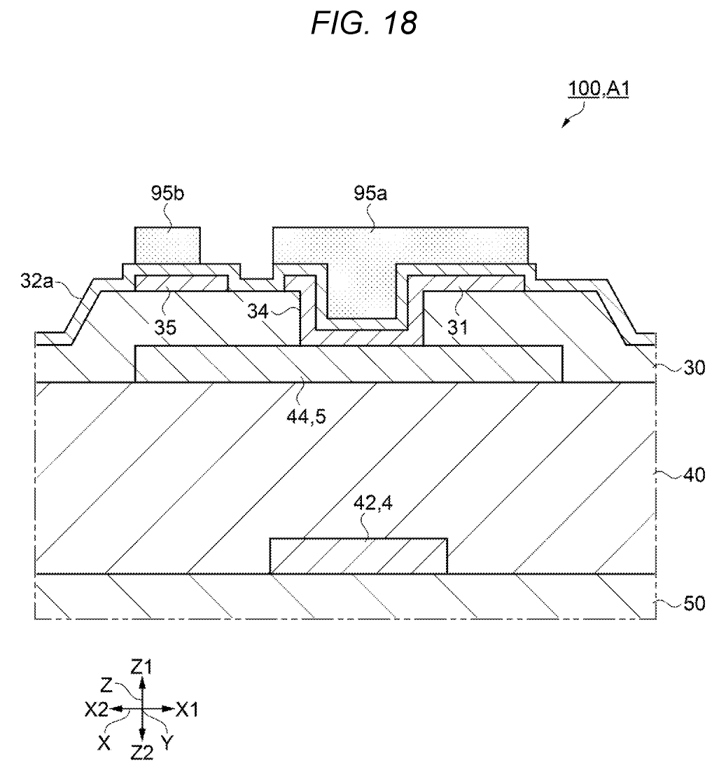

In the capacitance insulating layer forming step S3, as shown in FIG. 18, an insulating layer 32a serving as a precursor of the capacitance insulating layer 32 is formed. Subsequently, resist patterns 95a, 95bare formed at predetermined positions at the insulating layer 32a. The resist pattern 95ais disposed so as to cover the capacitance electrode 31. The resist pattern 95bis disposed corresponding to the conductive layer 35, and is disposed so that a part of the insulating layer 32a at the conductive layer 35 is exposed.

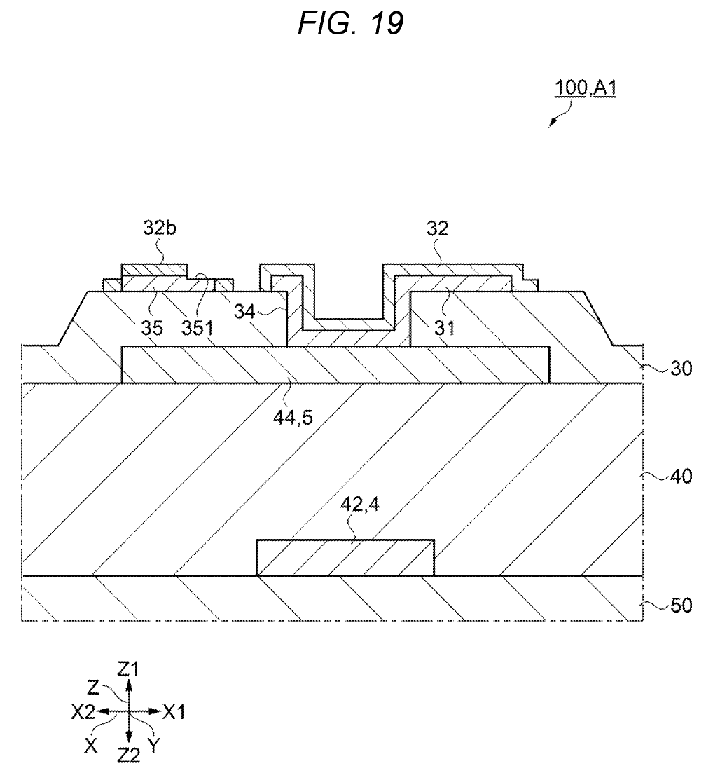

In the first region forming step S4, as illustrated in FIG. 19, the capacitance insulating layer 32, the region 351, and the insulating layer 32b are formed by etching the insulating layer 32a using the resist patterns 95a, 95b as masks.

The region 351 is a portion of the conductive layer 35 that is not covered with the resist pattern 95b (see FIG. 18), and is a surface obtained by half-etching and digging, in the Z2 direction, an upper surface of the conductive layer 35 exposed from the insulating layer 32a when etching the insulating layer 32a.

In the capacitance electrode forming step S5, as illustrated in FIG. 20, the conductive film 33a and the conductive film 33b serving as a precursor of the capacitance electrode 33 are deposited. On this occasion, the conductive film 33ais deposited at the region 351, and the conductive layer 35 and the conductive film 33a are electrically coupled to each other. Subsequently, a resist pattern 95cis formed at a predetermined position at the conductive film 33a and the conductive film 33b. The resist pattern 95chas a portion 95pcovering a part of the insulating layer 32b at the conductive layer 35.

In the second region forming step S6, as illustrated in FIG. 21, the conductive film 33a and the conductive film 33b are etched using the resist pattern 95c as a mask to form the capacitance electrode 33 and the region 352.

The region 352 is a portion of the conductive layer 35 that has not been covered with the resist pattern 95c (see FIG. 20), and is a surface obtained by half-etching and digging, in the Z2 direction, the upper surface of the conductive layer 35 exposed from the conductive film 33a, the conductive film 33b, and the insulating layer 32b when etching the conductive film 33a, the conductive film 33b, and the insulating layer 32b. Since the region 352 is a surface formed by half-etching the conductive layer 35, the conductive film 33b containing aluminum does not remain at the region 352.

At the conductive layer 35, the insulating layer 321 remains between the region 351 and the region 352. The insulating layer 321 is a portion of the insulating layer 32b that overlaps the portion 95p of the resist pattern 95c.

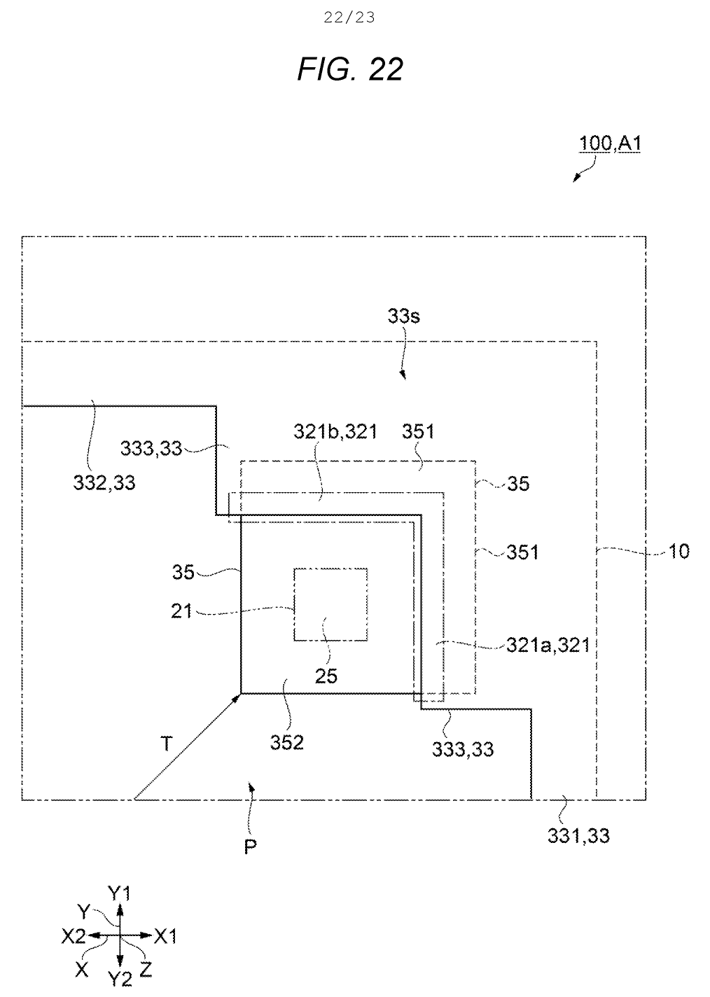

As illustrated in FIG. 22, the insulating layer 321 is disposed along an end portion of the protruding portion 333 of the capacitance electrode 33 at the conductive layer 35, and includes a portion 321a along the Y2 direction and a portion 321b along the X2 direction.

The insulating layer 321 is a portion where a part of the insulating layer 32b remains when the region 352 is formed. As described above, by leaving the insulating layer 321 at the conductive layer 35 between the region 351 and the region 352, the region 352 can be accurately formed while protecting the region 351 in the second region forming step S6. That is, in the second region forming step S6, it is possible to suppress the occurrence of defects such as penetration or disappearance due to excessive etching of the conductive layer 35.

As illustrated in FIG. 22, the region 351 is disposed at an opposite side of the portion 321a and the portion 321b of the insulating layer 321 to the opening T side of the pixel P, and the region 352 is disposed at the opening T side of the pixel P of the portion 321a and the portion 321b of the insulating layer 321. Therefore, even when the region 351 to which the capacitance electrode 33 is electrically coupled is provided to the conductive layer 35, since it is possible to suppress an increase in the area of the conductive layer 35, it is possible to suppress an influence on the opening T, that is, a decrease in the aperture ratio of the pixel P.

In the pixel contact forming step S7, as illustrated in FIG. 13, the contact hole 21 that penetrates the protective layer 22 and the interlayer insulating layer 20 and exposes the region 352 of the conductive layer 35 at the bottom is formed, and the contact plug 25 is formed in the contact hole 21.

As illustrated in FIG. 22, the contact hole 21 is disposed at a distance from the protruding portion 333 of the capacitance electrode 33 in the region 352 of the conductive layer 35.

Therefore, as described above, the conductive film 33b containing aluminum does not remain in the region 352. Therefore, when the contact hole 21 is formed, etching residue due to aluminum is not generated.

In the present embodiment, since the etching residue caused by aluminum is not generated, there is no need to remove the etching residue. Therefore, a possibility that the capacitance electrode 33 containing aluminum is side-etched when removing the etching residue to increase the risk of reliability in the pixel contact does not arise.

Here, the etching residue caused by aluminum is AlFx (aluminum fluoride). When the contact hole 21 is formed in the capacitance electrode 33, AlFx is formed by an etching gas containing an F (fluorine) component used when the contact hole 21 is formed, and thus an AlFx removal step of removing AlFx is required. In the AlFx removal step, the capacitance electrode 33 containing aluminum is side-etched by the etching gas containing Cl (chlorine), and there is a concern that the risk of reliability of the pixel contact increases.

In the pixel electrode forming step S8, as illustrated in FIGS. 12 and 13, the pixel electrode 10 is formed for each of the pixels P. Subsequently, the orientation film 12 is formed.

As described above, according to the liquid crystal device 300 as the electro-optical device of the present embodiment, the following advantages can be obtained.

The liquid crystal device 300 according to the present embodiment includes the transistor 1, the pixel electrode 10 disposed at the light incident side of the transistor 1, the capacitive element 3 including, in the layer between the transistor 1 and the pixel electrode 10, the capacitance electrode 31 as the first capacitance electrode and the capacitance electrode 33 as the second capacitance electrode that is electrically coupled to the transistor 1 and the pixel electrode 10 at the light incident side of the capacitance electrode 31 and is made of a material containing aluminum, and the conductive layer 35 electrically coupled to the capacitance electrode 33 in the same layer as the capacitance electrode 31 and electrically coupled to the pixel electrode 10 via the contact hole 21 disposed at a distance from the capacitance electrode 33 in the plan view.

As described above, in the capacitive element 3, the capacitance electrode 33 disposed at the light incident side is made of a material containing aluminum. Therefore, most of the light applied to the capacitive element 3 is reflected by the capacitance electrode 33. Therefore, it is possible to suppress the rise in temperature of the liquid crystal device 300.

Further, the pixel electrode 10 and the capacitance electrode 33 are electrically coupled to each other via a contact hole 21 disposed at a distance from the capacitance electrode 33. Therefore, when the contact hole 21 is formed, since the etching residue caused by aluminum is not generated, a step of removing the etching residue becomes unnecessary. When the step of removing the etching residue is performed, the capacitance electrode 33 containing aluminum is side-etched, and a risk of reliability occurs in the pixel contact. However, according to the present embodiment, since the step of removing the etching residue is unnecessary, the risk of reliability does not occur in the pixel contact. Therefore, according to the present embodiment, it is possible to realize the liquid crystal device 300 having high reliability.

In the liquid crystal device 300 according to the present embodiment, the capacitance electrode 33 as the second capacitance electrode includes the extending portion 331 as the first extending portion extending along the Y2 direction as the first direction, the extending portion 332 as the second extending portion extending along the X2 direction as the second direction crossing the Y2 direction, and the protruding portion 333 protruding toward the opening T side of the pixel P in the corner portion 33s defined by the extending portion 331 and the extending portion 332, and the protruding portion 333 of the capacitance electrode 33 and the region 351 as the end portion of the conductive layer 35 are electrically coupled to each other.

As described above, the capacitance electrode 33 includes the extending portion 331 extending along the Y2 direction and the extending portion 332 extending along the X2 direction. Therefore, since the area of the capacitance electrode 33 can be increased, the capacitance of the capacitive element 3 can be increased.

Further, since the protruding portion 333 of the capacitance electrode 33 and the region 351 of the conductive layer 35 are electrically coupled to each other, it is possible to suppress an influence on the opening T, that is, a reduction in the aperture ratio of the pixel P, and to realize the liquid crystal device 300 capable of performing bright display.

In the liquid crystal device 300 of the present embodiment, the capacitance electrode 33 as the second capacitance electrode includes the conductive film 33a as the first film containing titanium nitride and the conductive film 33b as the second film containing aluminum at the light incident side of the conductive film 33a.

As described above, in the capacitance electrode 33, the conductive film 33b containing aluminum which is a high reflection film is disposed at the light incident side of the conductive film 33a containing titanium nitride which is a low reflection film, and the conductive film 33a which is a low reflection film is disposed at the side opposite to the light incident side of the conductive film 33b which is a high reflection film, that is, at the transistor 1 side.

Therefore, since the capacitance electrode 33 can reflect the light incident from the light incident side by the conductive film 33b which is the high reflection film, it is possible to suppress the rise in temperature of the liquid crystal device 300, and even when the light is incident between the layers of the light blocking region S, the light is absorbed by the conductive film 33a which is the low reflection film, and thus it is possible to suppress the generation of the stray light and to suppress the deterioration of the display quality.

The liquid crystal device 300 of the present embodiment includes the capacitance insulating layer 32 disposed between the capacitance electrode 31 as the first capacitance electrode and the capacitance electrode 33 as the second capacitance electrode, and the insulating layer 321 disposed in the same layer as the capacitance insulating layer 32 so as to overlap the conductive layer 35, and the capacitance electrode 33 overlaps the conductive layer 35 in the plan view and is electrically coupled to the conductive layer 35 exposed from the insulating layer 321.

As described above, the capacitance electrode 33 and the conductive layer 35 overlap each other in the region 351 and are electrically coupled to each other. Therefore, by adopting a structure in which the capacitance electrode 33 is stacked on the conductive layer 35, the conductive layer 35 and the capacitance electrode 33 can be electrically coupled. Therefore, it is possible to improve the reliability of conduction with a simple configuration, and to easily perform manufacturing.

In the liquid crystal device 300 according to the present embodiment, the insulating layer 321 includes the portion 321a as the first portion along the Y2 direction as the first direction and the portion 321b as the second portion along the X2 direction as the second direction crossing the Y2 direction, and the conductive layer 35 includes the region 351 as the first region exposed from the insulating layer 321 at the opposite side of the portion 321a and the portion 321b to the opening T side of the pixel P in the plan view.

As described above, since the region 351 electrically coupled to the capacitance electrode 33 is disposed at the opposite side of the portion 321a and the portion 321b to the opening T side of the pixel P in the plan view, it is possible to suppress the influence on the opening T, that is, a reduction in the aperture ratio of the pixel P, and it is possible to realize the liquid crystal device 300 capable of performing bright display.

In the liquid crystal device 300 of the present embodiment, the conductive layer 35 has the region 352 as the second region exposed from the insulating layer 321 at the opening T side of the pixel P of the portion 321a as the first portion and the portion 321b as the second portion in the plan view, and the contact hole 21 is disposed at the opening T side of the pixel P with respect to the portion 321a and the portion 321b in the plan view.

As described above, the region 352 is disposed at the opening T side of the pixel P of the portion 321a and the portion 321b of the insulating layer 321, and the region 351 is disposed at the opposite side of the portion 321a and the portion 321b of the insulating layer 321 to the opening T side of the pixel P.

Therefore, the region 351 and the region 352 can be provided to the conductive layer 35 while suppressing an increase in the area of the conductive layer 35. Therefore, it is possible to suppress the influence on the opening T, that is, the reduction in the aperture ratio of the pixel P, and it is possible to realize the liquid crystal device 300 capable of performing bright display.

Furthermore, by disposing the portion 321a and the portion 321b of the insulating layer 321 between the region 351 and the region 352, the region 351 and the region 352 can be accurately formed. Specifically, it is possible to suppress the conductive layer 35 from being excessively etched by the etching when forming the region 352, and to suppress the occurrence of defects such as penetration or disappearance.

### 2. Embodiment 2

FIG. 23 is a schematic diagram showing an example of an electronic apparatus, and is a schematic diagram showing a schematic configuration of a projection-type display apparatus 1000 as the electronic apparatus.

The projection-type display apparatus 1000 is, for example, a three-plate projector including three liquid crystal devices 300 described above. A liquid crystal device 300R corresponds to a red display color, a liquid crystal device 300G corresponds to a green display color, and a liquid crystal device 300B corresponds to a blue display color. A controller 1005 includes, for example, a processor and a memory, and controls operations of the liquid crystal devices 300R, 300G, and 300B.

An illumination optical system 1001 supplies red light RL, green light GL, and blue light BL out of the light emitted from an illumination device 1002 as a light source to the liquid crystal device 300R, the liquid crystal device 300G, and the liquid crystal device 300B, respectively. The liquid crystal devices 300R, 300G, and 300B function as light modulation devices that modulate the colored light RL, GL, and BL incident from the illumination optical system 1001, respectively, in accordance with an image to be displayed.

A projection optical system 1003 combines light output from the liquid crystal device 300R, light output from the liquid crystal device 300G, and light output from the liquid crystal device 300B with each other, and projects the combined light onto a screen 1004.

As described above, the projection-type display apparatus 1000 as the electronic apparatus of the present embodiment includes the liquid crystal devices 300 described above.

Therefore, by adopting the liquid crystal device 300 in which the rise in temperature is suppressed, it is possible to improve the performance of the projection-type display apparatus 1000.

Note that the electronic apparatus is not limited to the three-plate projector presented by way of example. For example, the electronic apparatus may be a single-plate projector, a two-plate projector, or a projector including four or more liquid crystal devices 300. In addition, the electronic apparatus may be a smartphone, a personal digital assistant (PDA), a camera, a television set, a car navigation device, a personal computer, a display, electronic paper, a calculator, a video phone, a point of sale (POS) system, a printer, a scanner, a copier, a video player, an apparatus including a touch panel, and so on.

Although the preferred embodiment is described hereinabove, the present disclosure is not limited to the embodiment described above. In addition, the configuration of each element in the present disclosure can be replaced with any configuration that exhibits substantially the same function as that of the embodiment described above, and can be added with any configuration.

What is claimed is:

1. An electro-optical device comprising:
a transistor;
a pixel electrode disposed at a light incident side of the transistor;
a capacitive element including, in a layer between the transistor and the pixel electrode, a first capacitance electrode and a second capacitance electrode that is electrically coupled to the transistor and the pixel electrode at a light incident side of the first capacitance electrode and is made of a material containing aluminum; and
a conductive layer that is formed in a same layer as the first capacitance electrode and is electrically coupled to the second capacitance electrode and is electrically coupled to the pixel electrode via a contact hole disposed at a distance from the second capacitance electrode in a plan view.

2. The electro-optical device according to claim 1, wherein
the second capacitance electrode includes a first extending portion extending along a first direction, a second extending portion extending along a second direction crossing the first direction, and a protruding portion protruding toward an opening side of a pixel at a corner portion defined by the first extending portion and the second extending portion, and
the protruding portion of the second capacitance electrode and an end portion of the conductive layer are electrically coupled to each other.

3. The electro-optical device according to claim 1, wherein
the second capacitance electrode includes a first film containing titanium nitride and a second film containing aluminum at a light incident side of the first film.

4. The electro-optical device according to claim 1, further comprising:
a capacitance insulating layer disposed between the first capacitance electrode and the second capacitance electrode; and
an insulating layer disposed in a same layer as the capacitance insulating layer so as to overlap the conductive layer, wherein
the second capacitance electrode overlaps the conductive layer in the plan view and is electrically coupled to the conductive layer exposed from the insulating layer.

5. The electro-optical device according to claim 4, wherein
the insulating layer includes a first portion along a first direction and a second portion along a second direction crossing the first direction, and
the conductive layer includes a first region exposed from the insulating layer at an opposite side of the first portion and the second portion to an opening side of a pixel.

6. The electro-optical device according to claim 5, wherein
the conductive layer includes a second region exposed from the insulating layer at the opening side of the pixel of the first portion and the second portion in the plan view, and
the contact hole is disposed at the opening side of the pixel of the first portion and the second portion in the plan view.

7. An electronic apparatus comprising
the electro-optical device according to claim 1.
